(19) United States
(12) Patent Application Publication
(10) Pub. No.: US 2005/0110497 A1
(43) Pub. Date: May 26, 2005

(54) Spark detection apparatus and method that senses the battery voltage

(76) Inventor: William Michael Kayser, Brooklyn Park, MN (US)

Correspondence Address: William M. Kayser, 6408 81st Avenue North, Brooklyn Park, MN, 55445, US

(21) Appl. No.: 10/721,024

(22) Filed: Nov. 24, 2003

(51) Int. Cl. G01R 31/36

(52) U.S. Cl. 324/393; 324/771

(57) ABSTRACT

A spark detection apparatus and method for internal combustion engines that use sparks to ignite their fuel is disclosed. The detection apparatus includes a spark detector with improved accuracy, safety, and ease of connection over the current art.

This specification discloses a spark detection apparatus and method for internal combustion engines that use sparks to ignite their fuel. The detection apparatus includes a spark detector with improved accuracy, safety, and ease of connection over the current art.

### FIELD OF THE INVENTION

The invention is in the field of sensors that detect sparks in spark-ignited internal combustion engines.

### BACKGROUND OF THE INVENTION

In the current art, engine sparks are detected by devices that are placed on or near the electrical circuits that either generate those sparks or deliver those sparks to the engine. Examples of art related to the detection of spark pulses include U.S. Pat. Nos. 4,812,979 titled “Method and Apparatus for Analyzing the Performance of an Internal Combustion Engine” issued to Hermann and 5,258,753 titled “Digital Engine Analyzer” issued to Jonker. These both teach engine analyzers in which spark pulses are used to show how well an engine is performing, and neither one teaches detecting spark pulses with a sensor across the input power supply of the engines spark generating circuitry. Since there are no examples of devices or methods that detect sparks by sensing battery or power supply voltages, there is no closely related art to cite.

### SUMMARY OF THE INVENTION

The invention provides information about the functionality of spark-ignited engines through an analysis of the voltage of the electrical power means that supplies power to the engine's electric spark generating means. For most such engines, this power supply is a battery. The invention provides safer and easier accesses to spark signals, along with a more accurate output than the state of the art provides. The invention can provide a more accurate signal because the signal,it detects,is only a few micro-seconds in duration, whereas the spark pulses that are detected by the current art are hundreds of times longer in duration and thus subject to more time-related inaccuracies. The invention provides a safer access to the signal to be detected because battery voltages are low and safe, whereas spark voltages are high and thus potentially painful or life threatening, as well as sources of accidental ignitions of flammable vapors that are often in the immediate vicinity.

The fact that the invention provides an easier access to spark signals is especially important because increasing numbers of new engines have spark generators and wires that are shielded from outside access. Aircraft spark circuits have been shielded and virtually impossible to analyze for many years. Now, some engines are using coil lug systems that take the spark signal away from outside access, while others use printed circuit boards on top of spark plugs that block access to spark signals. However, regardless of how difficult the spark signal itself is to access, the power supply voltages that the invention uses are highly accessible.

### BRIEF DESCRIPTION OF THE DRAWINGS

FIG. 1: A Preferred Embodiment of the Invention

FIG. 2: Invention's Output Signal when Cylinder 3 Fires

FIG. 3: Invention's Output Signal when Cylinders 1, 2, 3 and 4 Fire

### DETAILED DESCRIPTION OF THE INVENTION

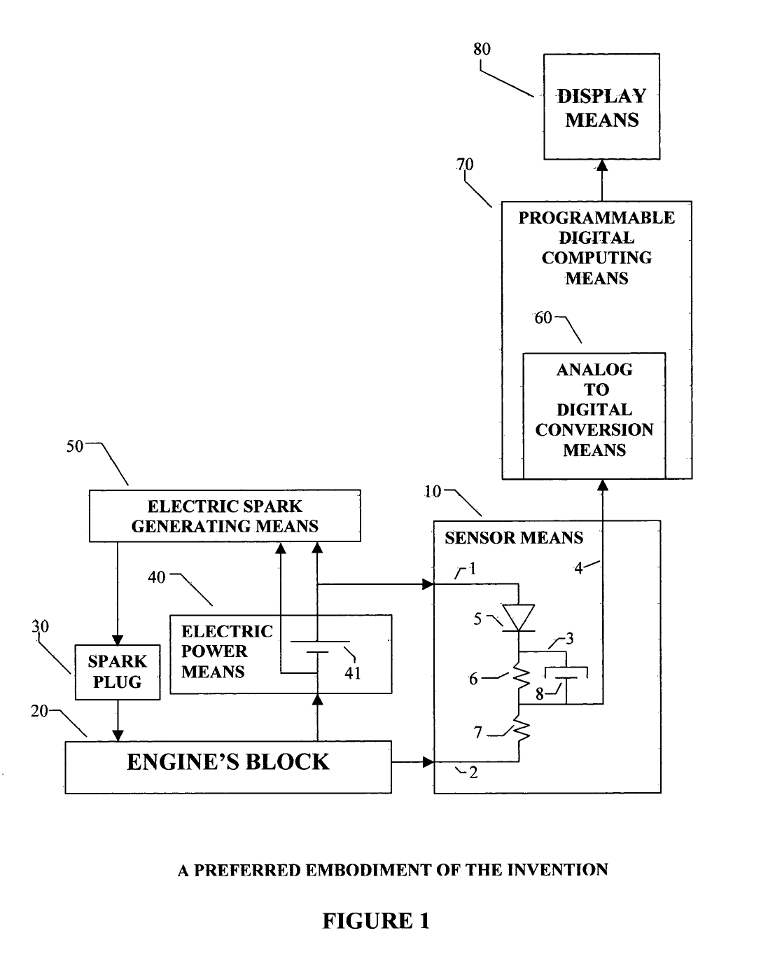

A preferred embodiment of the invention uses standard electrical components, a digital computer and software to detect and process signals from battery voltages. A block diagram and schematic of these devices is shown in FIG. 1. The circuitry of a preferred embodiment is shown inside the box labeled SPARK SENSOR 1-0. At has diode 5, capacitor 6 and resistors 7 and 8. Diode 5, resistor 6 and resistor 7 are connected in series, while capacitor 8 is connected in parallel with resistor 6. Diode 5 is a standard signal diode, resistor 6 is a 10,000,000 ohm resistor, resistor 7 is a 200,000 ohm resistor, and capacitor 8 is a 5 micro-farad capacitor. The spark sensor connects to the anode of battery 41 in ELECTRIC POWER MEANS 40 at node 1, and it connects to ENGINE BLOCK 20 (which is connected to the cathode of battery 41) at node 2.

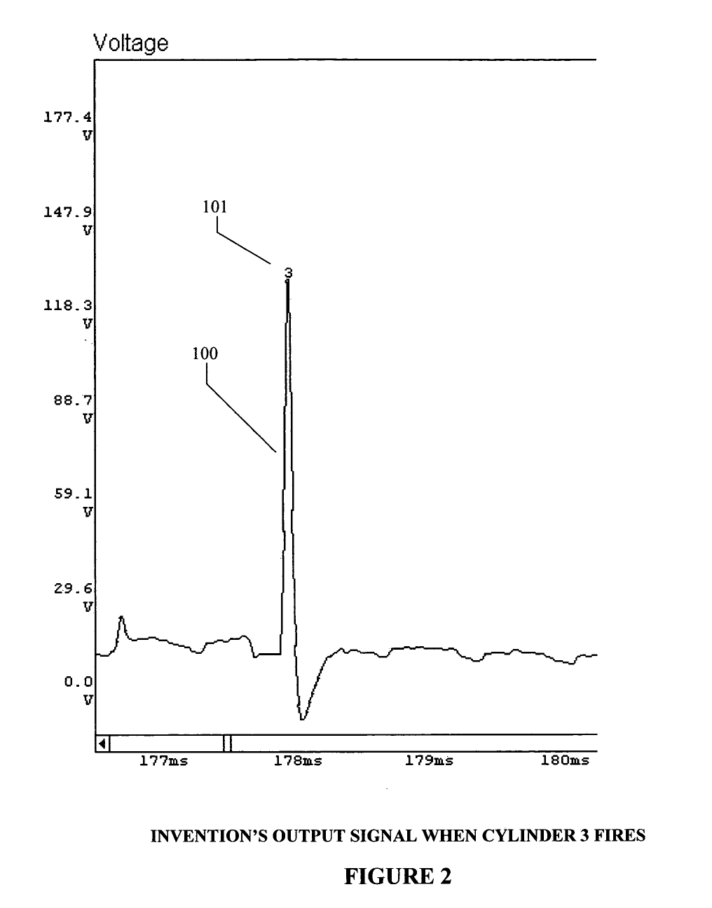

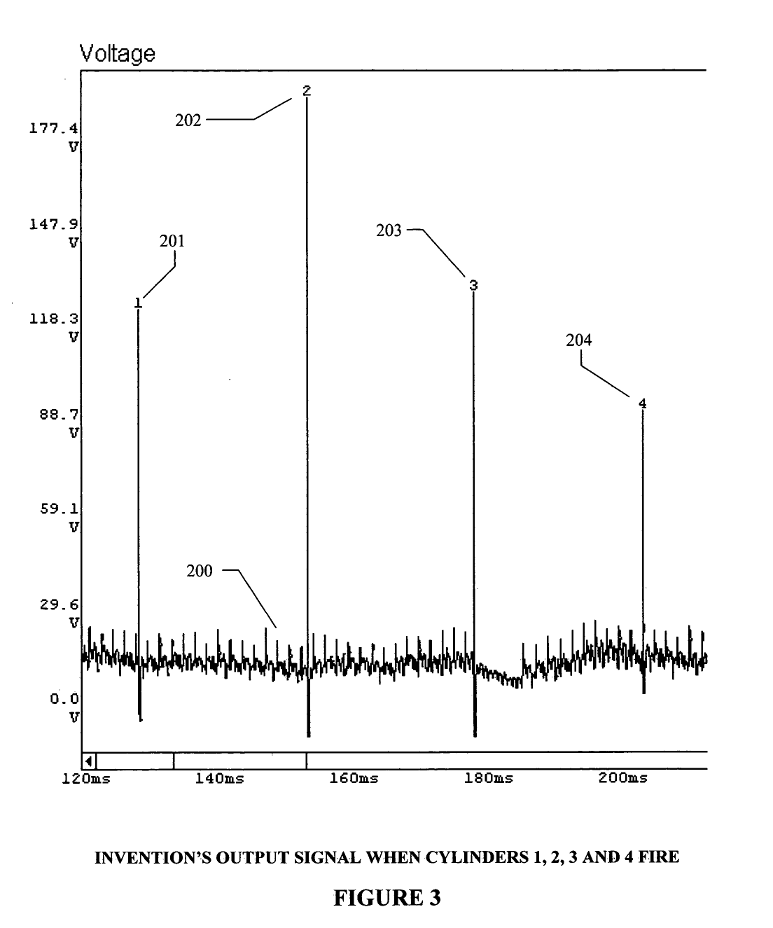

FIG. 2 shows the output of SENSOR MEANS 10 in waveform 100 over a period of about five milliseconds, and it shows the firing of one cylinder. FIG. 3 shows the output of SENSOR MEANS 10 in waveform 200 over a period of about eighty milliseconds, and it shows the firing of four cylinders.

The output of SENSOR MEANS 10 that is shown in waveforms 100 and 200 has consistent large voltage spikes that are read by ANALOG-TO-DIGITAL CONVERTING MEANS 60 and analyzed by PROGRAMMABLE DIGITAL COMPUTING MEANS 70. These 'spikes occur whenever ELECTRIC SPARK GENERATING MEANS 50 delivers a spark to ENGINE BLOCK 20 through SPARK PLUG 30. Cylinder numbers 101, 201, 202, 203 and 204 that are visible above waveforms 100 and 200, and they indicate the time when that cylinder's spark occurred.

The invention herein should not be construed as limited to the particular forms described because these are to be regarded as illustrative rather than restrictive. The essence of the invention is that it detects signals on the power inputs to spark generators that were not previously known to either exist or be detectable. Therefore, this patent disclosure covers all devices and methods that detect sparks based on the detection of signals from power supply outputs that are used to power spark generating devices.

1. An apparatus for detecting generated sparks, where an electrical power means supplies power to a spark generating means and where the electrical power supplied by the electrical power means to the spark generating means is detected by a sensor means so as to produce an output that is related to the occurrence of generated sparks.

2. The apparatus of claim 1 wherein the generated sparks are used to ignite fuel inside a spark-ignited internal combustion engine.

3. The apparatus of claim 1 wherein the output of the sensor means is transmitted to a computing means so as to provide diagnostic information.

4. The apparatus of claim 1 wherein the sensor means includes the electronic circuitry shown in the box labeled “SENSOR MEANS” in FIG. 1.

5. A method for detecting generated sparks, where an electrical power means supplies power to a spark generating means and where the electrical power supplied by the electrical power means to the spark generating means is detected by a sensor means so as to produce an output that is related to the occurrence of generated sparks.

6. The method of claim 1 wherein the generated sparks are used to ignite fuel inside a spark-ignited internal combustion engine.

7. The method of claim 1 wherein the output of the sensor means is transmitted to a computing means so as to provide diagnostic information.
